(19) United States
(12) Patent Application Publication
(10) Pub. No.: US 2012/0183767 A1
(43) Pub. Date: Jul. 19, 2012

(54) HEXAGONAL REO TEMPLATE BUFFER FOR III-N LAYERS ON SILICON

(76) Inventors: Rytis Dargis, Fremont, CA (US); Andrew Clark, Los Altos, CA (US); Michael Lebby, Apache Junction, AZ (US)

(21) Appl. No.: 13/328,270

(22) Filed: Dec. 16, 2011

Related U.S. Application Data
(63) Continuation-in-part of application No. 12/708,969, filed on Feb. 19, 2010.

(51) Int. Cl. B32B 9/04; C30B 23/02; C30B 25/02; B32B 5/00

(52) U.S. Cl. 428/336; 428/446; 117/106

(57) ABSTRACT

A III-N on silicon structure including a substrate of single crystal silicon with a cubic crystal structure and a layer of single crystal III-N material. First and second single crystal transition layers are positioned in overlying relationship with the layers graduated from a cubic crystal structure at one surface to a hexagonal crystal structure at an opposed surface. The first and second transition layers are positioned between the substrate and the layer of III-N material with the one surface lattice matched to the substrate and the opposed surface lattice matched to the layer of III-N material.

### CROSS-REFERENCE TO RELATED APPLICATION

This application is a Continuation in Part of copending U.S. patent application Ser. No. 12/708,969, filed 19 Feb. 2010.

### FIELD OF THE INVENTION

This invention relates to the deposition of III-N layers of material on silicon and more specifically to the provision of a III-N template buffer to enhance the deposition.

### BACKGROUND OF THE INVENTION

It has been found that III-N layers, e.g. GaN, on silicon substrates are a desirable semiconductor material in many electronic and photonic applications. However, there is a substantial difference in crystal lattice construction between III-N materials and silicon. One of the major problems is the fact that silicon has a cubic crystal lattice while the III-N oxide materials, such as GaN, have a hexagonal crystal lattice. Straightforward growth of hexagonal rare earth oxides on silicon leads to the formation of a polycrystalline layer that is not suitable for the growth of III-N material. Further, mechanically thick III-N on a silicon substrate is a challenge since the III-N layer tends to crack and the induced wafer bow can make it very difficult to process the wafer.

It would be highly advantageous, therefore, to remedy the foregoing and other deficiencies inherent in the prior art.

An object of the present invention is to provide a new and improved hexagonal rare earth template buffer for the growth of single crystal III-N layers of material on silicon substrates.

Another object of the present invention is to provide a template buffer to enhance the deposition of single crystal III-N materials on a silicon substrate.

Another object of the present invention is to provide a new and improved method of depositing single crystal III-N materials on a silicon substrate.

### SUMMARY OF THE INVENTION

Briefly, to achieve the desired objects and aspects of the instant invention in accordance with a preferred embodiment thereof, provided is a III-N on silicon structure including a substrate of single crystal silicon with a cubic crystal lattice, a layer of a single crystal III-N material with a hexagonal crystal lattice, and first and second single crystal transition layers positioned in overlying relationship. The first and second transition layers are graduated from a cubic crystal lattice at one surface to a hexagonal crystal lattice at an opposed surface. The first and second transition layers are positioned between the substrate and the layer of second material with the one surface substantially lattice matched to the substrate and the opposed surface substantially lattice matched to the layer of single crystal III-N material. In addition, the first transition layer is selected to have a lattice spacing closely matched to silicon.

The desired objects and aspects of the instant invention are further achieved in accordance with a preferred method of fabricating a III-N on silicon structure including the step of providing a single crystal substrate including silicon with a cubic crystal lattice. The method further includes the step of depositing a first single crystal transition layer and a second single crystal transition layer in overlying relationship on the substrate with the first and second transition layers, respectively, graduated from a cubic crystal lattice at a surface substantially lattice matched to the substrate to a hexagonal crystal lattice at an opposed surface. The method further includes the step of depositing a layer of single crystal III-N material with a hexagonal crystal lattice on the opposed surface of the first and second transition layers. The layer of single crystal second material is substantially lattice matched to the opposed surface. In the method the lattice match includes selecting the first transition layer to have a lattice spacing closely matched to silicon.

### BRIEF DESCRIPTION OF THE DRAWINGS

Specific objects and advantages of the instant invention will become readily apparent to those skilled in the art from the following detailed description of a preferred embodiment thereof taken in conjunction with the drawings, in which:

FIG. 1 illustrates the different crystal structures for the rare earth oxides;

FIG. 2 is a simplified sectional view of a solar cell with rare earth transition layers in accordance with the present invention;

FIG. 3 is a simplified graphical representation of a process for depositing rare earth transition layers in accordance with the present invention;

FIG. 4 is a simplified cross-sectional layer diagram of one embodiment of a hexagonal rare earth template buffer matching a single crystal III-N layer of material to a silicon substrate in accordance with the present invention; and

FIGS. 5-7 are sequential simplified cross-sectional layer diagrams illustrating steps in the growth of a hexagonal rare earth template buffer matching a single crystal III-N layer of material to a silicon substrate in accordance with the present invention.

### DETAILED DESCRIPTION OF THE DRAWINGS

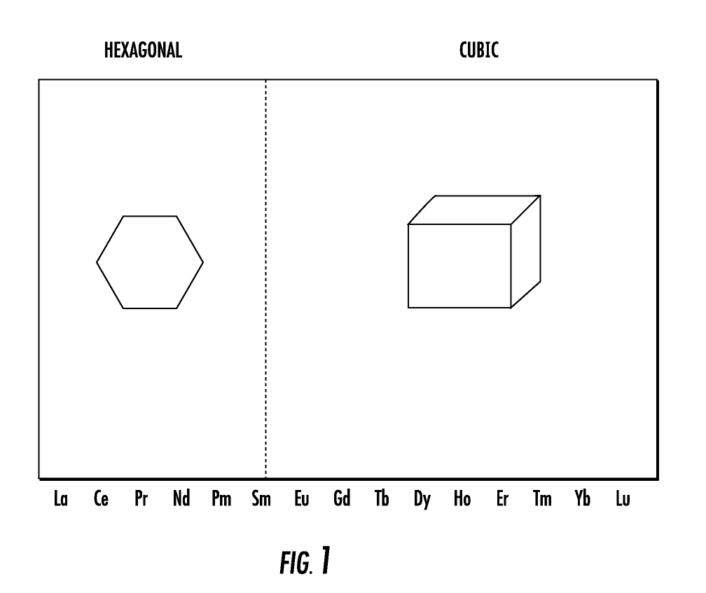

A major problem with any attempts to incorporate III-N materials in a single crystal growth or formation with silicon is the particular crystal structure of the material. Silicon has a cubic crystal lattice and many other higher bandgap materials, such as GaN, InGaN, etc. have a hexagonal crystal lattice. Epitaxially growing hexagonal crystals onto cubic crystals will generate huge lattice mismatch and crystal defects which will limit the usefulness of the material for device design. Thus, it is difficult to incorporate single crystal III-N materials onto a single crystal silicon substrate since the different crystals of the two materials are difficult or impossible to lattice match. Typical hexagonal and cubic crystal structures of rare earth materials are illustrated in FIG. 1. The different crystal structures for the rare earth oxides illustrated in FIG. 1 show that rare earth materials can be engineered to align on either cubic or hexagonal lattice structures.

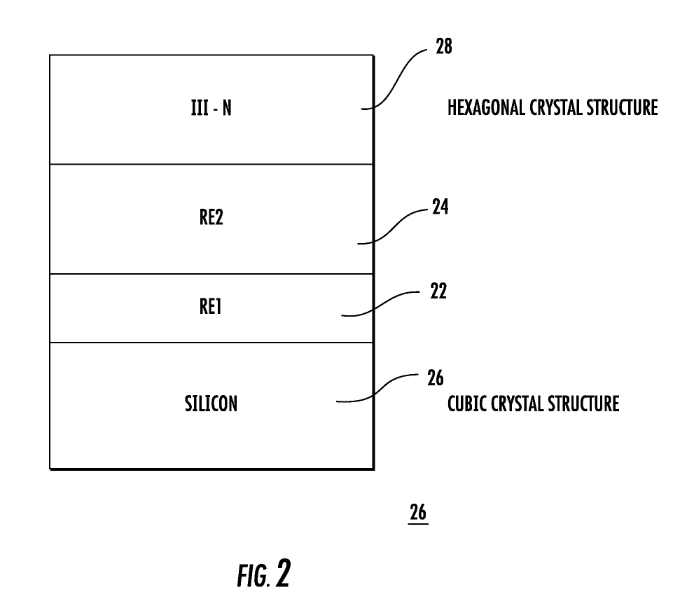

Turning to FIG. 2, a simplified sectional view of a III-N on silicon structure, designated 20, in accordance with the present invention is illustrated. Basically, layers of single crystal rare earth oxides are deposited as transition layers 22 and 24 on a single crystal silicon substrate 26, after which a single crystal layer 28 of III-N material is deposited. Silicon substrate 26 is any single crystal structure, such as a silicon wafer, any portion of a silicon wafer, or chip, etc. Substrate 26 includes single crystal silicon which, it will be understood, is or may be a standard well know single crystal silicon wafer or portion thereof generally known and used in the semiconductor industry. Single crystal silicon substrate 26, it will be understood, is not limited to any specific crystal orientation but could include <111> silicon, <110> silicon, <100> silicon or any other orientation or variation known and used in the art. Here it should be understood that the term “single crystal” is used to denote crystalline silicon grown or formed as a single continuous crystal well known in the art. Generally, throughout this disclosure whenever rare earth materials are mentioned it will be understood that “rare earth” materials are defined as any of the lanthanides as well as scandium and yttrium. Also, layer 28 will include a III-N material which is defined as a nitride of any of the metals from the III group in the periodic table or combinations thereof. In a preferred embodiment the III-N material is GaN, which is a semiconductor material useful in electronic and photonic applications.

As explained above, silicon has a cubic crystal structure and III-N materials, such as GaN, have a hexagonal cubic structure. To allow the continuous single crystal growth of structure 20, first transition layer 22 of an oxide of rare earth or the like is chosen from a material having a cubic crystal structure and a lattice spacing generally selected to closely or approximately match the lattice spacing of silicon substrate 26 or to provide a predetermined amount of stress or mismatch in lattice spacing to compensate for cracking and/or bowing in subsequent layers. For example, Gd₂O₃ has a cubic crystal structure and a lattice spacing of 10.81 Å compared to 2a_{Si} with a lattice spacing of 10.86 Å, or approximately two times the lattice spacing of silicon. Thus, crystal nodes of the Gd₂O₃ substantially match with every-other crystal node of the silicon and the Gd₂O₃ is therefore considered to be lattice coincident with silicon, both spacing and structure or lattice.

Illustrated in FIG. 1 are the different crystal structures for rare earth oxides. Also, some other materials classified in the IIIB group of the periodic table such as scandium (Sc), have a hexagonal crystal structure. Scandium and yttrium are considered rare earths. In some specific applications cubic bixbyite material could be included in layer 22 and, to this end, layer 22 will be referred to in at least some instances as a “cubic crystal lattice material”. As an example of material that can be used in layer 22, Eu₂O₃ has a cubic crystal structure and a lattice spacing of 10.9 Å so that it is lattice matched to silicon and single crystal layer 22 can be grown on single crystal silicon layer 26 with little or no stress or strain in or between substrate 26 and layer 22.

Second layer 24 of a single crystal oxide of rare earth or the like is chosen from a material having a hexagonal crystal structure. As an example, Sc₂O₃ has a hexagonal crystal structure and a lattice spacing of 3.2 Å so that it is lattice matched to GaN. It should be understood that some materials selected for either layer 24 or layer 28 may have a crystal spacing that is approximately a multiple of the other material's spacing but as long as the crystal nodes of one of the materials substantially matches with some of the nodes (e.g. every-other node) in the adjacent material the crystal materials are considered to be substantially lattice coincident. Thus, single crystal III-N layer 28 can be grown on second single crystal layer 24 with little or no stress or strain in or between layers 28 and 24. As understood by the artisan, it is desirable to reduce or eliminate any substantial stress or strain in the crystal structure to promote crack, fracture and bowing free growth in layer 28. Note that small lattice mismatching, e.g. 1% or less, will generally produce small enough stress or strain that will not cause defects in the lattice match.

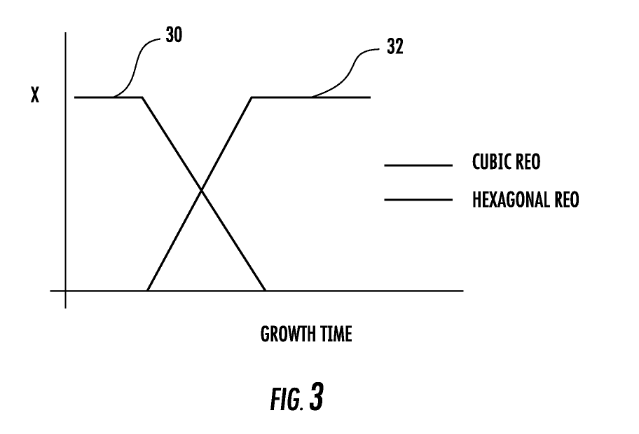

It will be noted that layers 22 and 24 are adjacent and generally layer 24 is epitaxially grown on layer 22. To allow the single crystal growth (e.g. layer 24 on layer 22) to be performed without undue crystal strain and defects, the first material (in this example Eu₂O₃) is grown generally as indicated by line 30 in FIG. 3. That is, the Eu₂O₃ is started at maximum growth and gradually reduced to zero. At approximately a mid point in the reduction of the growth of Eu₂O₃, the growth of Sc₂O₃ is started from zero and gradually increased to a maximum level as shown by line 32. Generally layers 22 and 24 are approximately a thousand angstroms thick with the gradation or gradual change starting at approximately the mid point of each layer. By gradually changing from the cubic crystal structure material to the hexagonal crystal structure material, crystal defects are avoided and both layers 22 and 24 are single crystal material at the junctions with layers 26 and 28, respectively.

The process described above allows III-N materials, such as GaN, to be grown or incorporated onto single crystal silicon in a structure such as illustrated in FIG. 2. Since all of the materials of structure 20 are single crystal materials, the entire cell can be grown, for example epitaxially, in a single process (i.e. in situ). Rare earth oxide layer 22 is grown directly on the surface of substrate 26 using any of the well known growth methods, such as MBE, MOCVD, PLD (pulsed laser deposition), sputtering, ALD (atomic layer deposition), or any other known growth method for thin films. Further, the growth method used will generally be used for all additional layers and may conveniently be employed to grow the entire structure in a continuous process sometimes referred to herein as performed within a one wafer single epitaxial process.

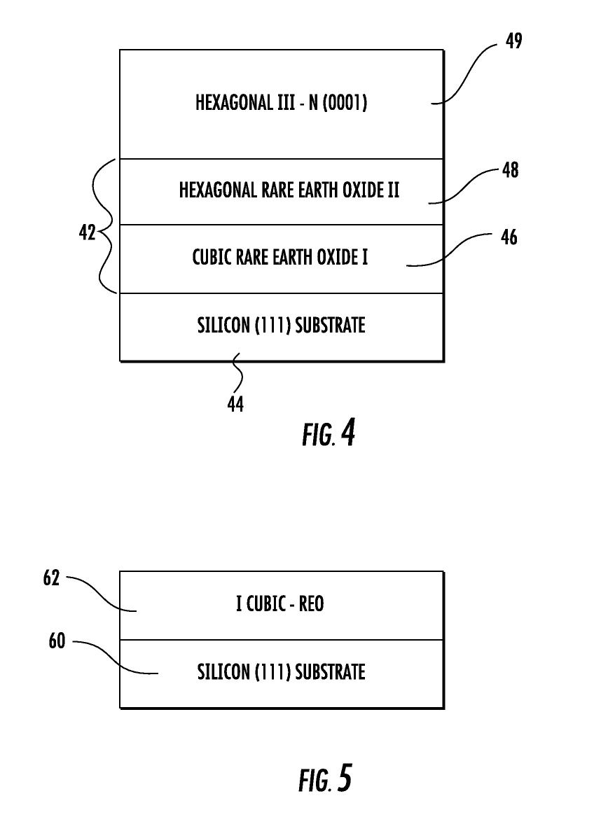

Turning to FIG. 4, a III-N on silicon structure 40 is illustrated that includes a multiple layer template buffer 42 designed to match single crystal III-N material to a silicon substrate. In this specific example, a silicon substrate 44 forms the base for the structure. A first layer 46 of single crystal rare earth oxide with a cubic crystal structure is grown or deposited on silicon substrate 44 and a second layer 48 of single crystal rare earth oxide with a hexagonal crystal structure is grown or deposited on layer 46 in a graduated process, e.g. as described above. A layer 49 of single crystal III-N material with a hexagonal crystal lattice, e.g. GaN, is deposited on layer 48 in an approximately lattice matched configuration. It should be understood that while single crystal silicon substrate 44 is illustrated in this specific embodiment as having a <111> crystal orientation, it is not limited to any specific crystal orientation but could include others as described above.

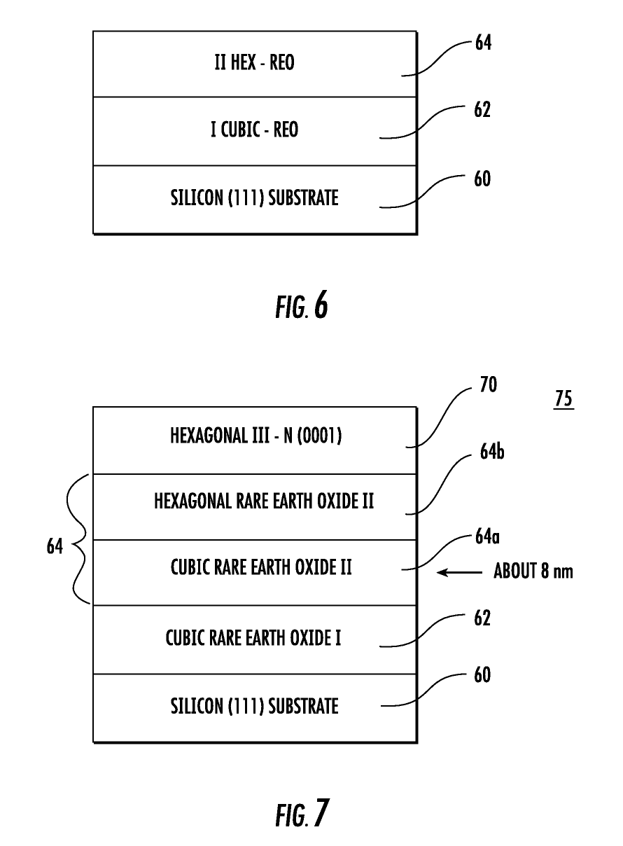

Turning now to FIGS. 5-7, an example of various steps in one specific method of fabricating a III-N on silicon structure in accordance with the present invention is illustrated. Specifically, FIG. 5 illustrates the growth of a first single crystal rare earth oxide layer 62 with a cubic crystal lattice on a silicon substrate 60. Some examples of cubic crystal lattice rare earth oxide materials are Gd₂O₃, Er₂O₃, Yb₂O₃, and Lu₂O₃. Using any of the closely matched materials results in a flat high crystal quality cubic rare earth oxide layer 62.

Referring specifically to FIG. 6, a second single crystal rare earth oxide layer 64 with a hexagonal crystal lattice is grown on first rare earth oxide layer 62. Some examples of hexagonal crystal lattice rare earth oxide materials are La₂O₃, Nd₂O₃, and Pr₂O₃. It has been noted that at the beginning of the growth of layer 64, the layer adopts the cubic structure of first rare earth oxide layer 62. At a critical thickness higher than approximately 8 nm, the crystal lattice of second rare earth oxide layer 64 starts to transform to hexagonal because that crystal lattice is energetically more favorable. After further growth, second rare earth oxide layer 64 exhibits a flat 2×2 reconstructed surface confirming its hexagonal crystal lattice structure.

Referring specifically to FIG. 7 the changing crystal structure of layer 64 is illustrated as two layers 64a and 64b. Layer 64a is approximately 8 nm thick, after which the crystal lattice formation begins to change to a hexagonal lattice, illustrated as layer 64b. Hexagonal rare earth oxide layer 64b is then used as a template to grow a layer 70 of single crystal III-n material with a hexagonal crystal lattice. Because the crystal lattice of template layer 64b can be selected to be substantially lattice matched to the III-N material of layer 70, the single crystal III-N material can be grown with substantially no stress and, therefore, substantially no cracking, fractures, or bowing. The result is a III-N on silicon structure 75 that can be relatively easily grown and which is useful in many electronic and photonic applications.

Thus, a new and improved III-N on silicon structure is disclosed that includes a rare earth template buffer matching a silicon substrate to a III-N semiconductor layer. The adjacent layers of III-N material and silicon are lattice matched by intermediate transition layers of single crystal rare earth oxides. The intermediate transition layers allow both the silicon and the III-N material to be substantially lattice matched to the adjacent layer. Basically, the cubic crystal structure of silicon is converted to a hexagonal crystal structure by gradation layers of rare earth oxide or the like. This lattice matching allows the entire structure to be grown in situ (i.e. one continuous process) and greatly reduces defects in the crystal structures.

Various changes and modifications to the embodiments herein chosen for purposes of illustration will readily occur to those skilled in the art. To the extent that such modifications and variations do not depart from the spirit of the invention, they are intended to be included within the scope thereof, which is assessed only by a fair interpretation of the following claims.

Having fully described the invention in such clear and concise terms as to enable those skilled in the art to understand and practice the same, the invention claimed is:

1. A III-N on silicon structure comprising:
a substrate including single crystal silicon with a cubic crystal lattice;
a layer of a single crystal III-N material with a hexagonal crystal lattice; and
first and second single crystal transition layers positioned in overlying relationship, with the first and second transition layers graduated from a cubic crystal lattice at one surface to a hexagonal crystal lattice at an opposed surface, and the first and second transition layers positioned between the substrate and the layer of second material with the one surface substantially lattice matched to the substrate and the opposed surface substantially lattice matched to the layer of single crystal III-N material.

2. A III-N on silicon structure as claimed in claim 1 wherein the layer of single crystal III-N material includes GaN.

3. A III-N on silicon structure as claimed in claim 1 wherein the first and second transition layers each include a rare earth oxide.

4. A III-N on silicon structure as claimed in claim 3 wherein the first transition layer includes one of Gd₂O₃, Er₂O₃, Yb₂O₃, and Lu₂O₃.

5. A III-N on silicon structure as claimed in claim 3 wherein the second transition layer includes one of La₂O₃, Nd₂O₃, and Pr₂O₃.

6. A III-N on silicon structure as claimed in claim 1 wherein the first transition layer includes a rare earth oxide with a cubic crystal lattice and the second transition layer includes a rare earth oxide with a first sub-layer having a cubic crystal lattice and a second sub-layer that gradually transitions from the cubic crystal lattice to a hexagonal crystal lattice.

7. A III-N on silicon structure as claimed in claim 6 wherein the first sub-layer of the second transition layer is approximately 8 nm thick.

8. A III-N on silicon structure as claimed in claim 1 wherein the first transition layer has a lattice spacing closely matched to silicon.

9. A III-N on silicon structure comprising:
a substrate of single crystal silicon with a cubic crystal lattice;
a first layer of single crystal rare earth oxide with a cubic crystal lattice deposited on the substrate and substantially crystal lattice matched to the substrate;
a second layer of single crystal rare earth oxide deposited on the first layer and substantially crystal lattice matched to the first layer, the second layer including a first sub-layer having a cubic crystal lattice and a second sub-layer that gradually transitions from the cubic crystal lattice to a hexagonal crystal lattice; and
a layer of single crystal III-N material with a hexagonal crystal lattice deposited on the second layer of single crystal rare earth oxide and substantially crystal lattice matched to the second sub-layer of the second layer of single crystal rare earth oxide.

10. A method of fabricating a III-N on silicon structure comprising the steps of:
providing a single crystal substrate including silicon with a cubic crystal lattice;
depositing a first single crystal transition layer and a second single crystal transition layer in overlying relationship on the substrate with the first and second transition layers, respectively, graduated from a cubic crystal lattice at a surface lattice matched to the substrate to a hexagonal crystal lattice at an opposed surface; and
depositing a layer of single crystal III-N material with a hexagonal crystal lattice on the opposed surface of the first and second transition layers, the layer of single crystal III-N material being lattice matched to the opposed surface.

11. A method as claimed in claim 10 wherein the step of depositing the first single crystal transition layer and the second single crystal transition layer and the step of depositing the layer of the single crystal III-N material are all performed in a single continuous operation in situ.

12. A method as claimed in claim 10 wherein the layer of single crystal III-N material includes GaN.

13. A method as claimed in claim 10 wherein the first and second transition layers each include a rare earth oxide.

14. A method as claimed in claim 13 wherein the first transition layer includes one of Gd₂O₃, Er₂O₃, Yb₂O₃, and Lu₂O₃.

15. A method as claimed in claim 13 wherein the second transition layer includes one of La₂O₃, Nd₂O₃, and Pr₂O₃.

16. A method as claimed in claim 10 wherein the first transition layer includes a rare earth oxide with a cubic crystal lattice and the second transition layer includes a rare earth oxide with a first sub-layer having a cubic crystal lattice and a second sub-layer that gradually transitions from the cubic crystal lattice to a hexagonal crystal lattice.

17. A method as claimed in claim 16 wherein the first sub-layer of the second transition layer is approximately 8 nm thick.

18. A method as claimed in claim 10 wherein the first transition layer has a lattice spacing closely matched to silicon.
